(19) United States
(12) Patent Application Publication
(10) Pub. No.: US 2008/0158023 A1
(43) Pub. Date: Jul. 3, 2008

(54) Apparatus and Method for Expressing Hangul

(75) Inventor: Hee Sung CHUNG, Chungcheongnam-do (KR)

Correspondence Address: GREENBLUM & BERNSTEIN, P.L.C., 1950 ROLAND CLARKE PLACE, RESTON, VA, 20191, US

(73) Assignee: NEOPAD CO., LTD., Seoul (KR)

(21) Appl. No.: 11/966,207

(22) Filed: Dec. 28, 2007

(30) Foreign Application Priority Data
Dec. 29, 2006 (KR) 10-2006-0137560

(51) Int. Cl. H03K 17/94

(52) U.S. Cl. 341/28

(57) ABSTRACT

The present invention relates to an apparatus and a method for expressing Hangul. More specifically, the present invention relates to an apparatus and a method for expressing Hangul by which Hangul can be inputted, without using a separate function key, to an information appliance with an input means which comprises a multi key to which a plurality of jamos (consonants and vowels of Hangul) are assigned.

### BACKGROUND OF THE INVENTION

1. Field of the Invention

The present invention relates to an apparatus and a method for expressing Hangul. More specifically, the present invention relates to an apparatus and a method for expressing Hangul by which Hangul can be inputted, without using a separate function key, to an information appliance with an input means which comprises a multi key to which a plurality of jamos (consonants and vowels of Hangul) are assigned.

2. Background of the Related Art

Any discussion of the prior art throughout the specification should in no way be considered as an admission that such prior art is widely known or forms part of common general knowledge in this field.

FIG. 1a illustrates a Hangul alignment of a conventional terminal keypad, which is disclosed in the Korean registered Patent No. 159191 and used for mobile phones made by Samsung electronics.

Referring to FIG. 1, the jamos [symbol] , [symbol] , and [symbol] are assigned to the number keys 1, 2, and 3 among the ten number keys, respectively, to be used to input vowels of Hangul, and consonants of Hangul are plurally assigned to the other number keys, i. e., the number keys 4 to 9 and 0. The Hangul alignment has a disadvantage in that it is difficult to tell what consonant is intended to be inputted when a key to which plural consonants are assigned is continuously inputted.

For example, when a user intends to input the word [symbol] using the consonants [symbol] and [symbol] assigned to the number key 5, the user orderly inputs [symbol] , [symbol] , [symbol] (pressing the number key 5 once), [symbol] (pressing the number key 5 twice continuously), [symbol] , and [symbol] . At this time, [symbol] is outputted by pressing the number key 5 once and [symbol] is outputted by pressing the same key twice, and [symbol] is again outputted by pressing the same key three times. Accordingly, this Hangul alignment requires a time interval to be made between input of [symbol] of [symbol] and input of [symbol] of [symbol] , or a function key to be used between them, so as to put a boundary between [symbol] of [symbol] and [symbol] of [symbol] .

This disadvantage is commonly applied to all the keys to which plural consonants are assigned, i. e., the number keys 4 to 9 and 0. Therefore, when a user continuously inputs letters assigned to one key to input a last letter of a syllable and a first letter of a next syllable, he or she should be careful to prevent an unwanted word from being inputted. In fact, unwanted words are often inputted in this Hangul alignment. This can cause users to get stressed.

FIG. 1b illustrates a Hangul alignment of a conventional terminal keypad, which is disclosed in the Korean registered Patent No. 291838 and used for mobile phones made by LG electronics.

Referring to FIG. 1b, in this Hangul alignment, a plurality of vowels are assigned to a key and one consonant is assigned to a key.

In this Hangul alignment, the letter keys [symbol] , [symbol] , [symbol] , [symbol] , and [symbol] and two function keys ‘*’ and [symbol] are used for inputting consonants. The consonants [symbol] , [symbol] , [symbol] , [symbol] , and [symbol] and the other consonants are inputted by pressing a corresponding letter key and/or a function key, considering shape of an intended consonant. Accordingly, a plurality of consonants such as [symbol] , [symbol] , [symbol] , [symbol] and [symbol] are actually assigned to the keys in this alignment. To input continuously letters assigned to a letter key without uncertainty in a boundary of characters, this alignment needs a function key to be used with a letter key.

According to this inputting method, it is possible to resolve the uncertainty in a boundary between syllables. However, this method has a disadvantage in that it requires users to perceive the consonants not shown on the letter keys and learn how to input them, and also it causes users to be stressed from a long distance between a letter key and a function key.

FIG. 1c illustrates a Hangul alignment of a conventional keypad, which is disclosed in the Korean publication No. 2004-61800 and used for mobile phones made by Pantech Group.

Referring to FIG. 1c, a plurality of consonants are assigned to the number keys 1, 2, 3, 5, and 6 to input Hangul. So, like the aforesaid inputting methods, this inputting method also causes uncertainty in inputting Hangul.

FIG. 1d illustrates a Hangul alignment of a conventional terminal keypad, which is disclosed in the Korean registered Patent No. 421545 and used for inputting Hangul in the mobile phones of SKY Teletec series.

Referring to FIG. 1d, a plurality of consonants are assigned to the number keys 1, 4, 5, 7, 8, and 0, and the function key # for inputting Hangul. Accordingly, this Hangul alignment also has the aforesaid problems.

FIG. 1e shows a Hangul alignment of a conventional terminal keypad which is used for inputting Hangul in the mobile phones of Motorola.

Referring to FIG. 1e, a plurality of consonants and vowels except the consonants [symbol] and [symbol] are assigned to the keys of the keypad, in which alignment, there are the aforesaid problems, too.

FIG. 1f illustrates a Hangul alignment of a conventional terminal keypad which is used for inputting Hangul in the Korean registered Patent No. 377432.

Referring to FIG. 1f, this alignment makes it a rule to assign a single consonant or vowel to each key. However, the aspirated counterparts and the double counterparts of the simple consonants [symbol] , [symbol] , [symbol] , [symbol] , [symbol] , and [symbol] are assigned to the keys of the simple consonants, respectively, and inputted in a two-stroke way using a separate function key. Accordingly, it is impossible to input Hangul without using a function key.

Meanwhile, in the case of a keyboard for a computer, the jamos [symbol] , [symbol] , [symbol] , [symbol] , [symbol] , [symbol] etc. are plurally assigned to the keys, and the letters in parentheses are inputted using the function key, shift key. It is inconvenient to press the shift key along with a key to which plural letters are assigned, when the letters in parentheses are intended to be inputted.

### SUMMARY OF THE INVENTION

Accordingly, the present invention is directed to an apparatus and a method for expressing Hangul that substantially obviates one or more problems due to limitations and disadvantages of the related art.

An object of the present invention is to provide an apparatus and a method for expressing Hangul, which enables Hangul to be inputted without a time gap between inputs or a use of a function key when a user inputs Hangul to an information appliance by means of an input means with a multi key to which a plurality of jamos are assigned.

Another object of the present invention is to provide an apparatus and a method for expressing Hangul, which can remove uncertainty in a boundary between jamos when a user inputs Hangul to an information appliance by means of an input means with a multi key to which a plurality of jamos are assigned. Such uncertainty is caused by continuously inputting jamos through multi keys.

To accomplish the above objects, according to one aspect of the present invention, there is provided an apparatus for expressing Hangul, which is used to input and output Hangul to an information appliance, the apparatus comprising: a Hangul combiner for distinguishing consonants of inputted jamos (consonants or vowels) into a chosung and a jongsung, and combining the inputted jamos to generate at least one series of characters including a syllable; a Hangul word information dictionary for defining series of characters including at least one syllable, and adding grammar information to each of the defined series of characters including at least one syllable; a character controller for deciding if the series of character generated by the Hangul combiner correspond to the series of characters defined by the Hangul word information dictionary; an output means for outputting the one with the highest output rank among the series of characters generated by the Hangul combiner to the information appliance and storing the rest with lower output ranks in a temporary storage; and a connection information table for providing connection information to decide if the series of character outputted to the information appliance can be connected to a next-inputted series of characters using the grammar information of the series of characters.

To accomplish the above objects, according to one aspect of the present invention, there is also provided an apparatus for expressing Hangul, which is used to input and output Hangul to an information appliance, the apparatus comprising: a Hangul combiner for combining inputted jamos to generate at least one series of characters including a syllable; a Hangul word connection definition dictionary for defining words including at least one syllable, and adding a list of words which can be connected to each of the defined words to make them function grammatically; a character controller for deciding if the series of character generated by the Hangul combiner correspond to the series of characters defined by the Hangul word connection definition dictionary; and an output means for outputting the one with the highest output rank among the series of characters generated by the Hangul combiner to the information appliance and storing the rest with lower output ranks in a temporary storage.

To accomplish the above objects, according to one aspect of the present invention, there is also provided an apparatus for expressing Hangul, which is used to input and output Hangul to an information appliance, the apparatus comprising: a Hangul combiner for combining inputted jamos to generate at least one series of characters including a syllable; a Hangul word dictionary for defining a word which includes at least one syllable and functions grammatically; a character controller for deciding if the series of characters generated by the Hangul combiner correspond to the word defined by the Hangul word dictionary; and an output means for outputting the one with the highest output rank among the series of characters generated by the Hangul combiner to the information appliance and storing the rest with lower output ranks in a temporary storage.

To accomplish the above objects, according to one aspect of the present invention, there is also provided an apparatus for expressing Hangul, which is used to input and output Hangul to an information appliance using an input means with at least one multi key to which a plurality of consonants are assigned, the apparatus comprising: a Hangul combiner for combining inputted jamos to generate at least one series of characters including a syllable; a Hangul input assistance dictionary for defining a word which has uncertainty in a boundary of series of characters among series of characters which are capable to be generated by inputting through the multi key; a character controller for deciding if a plurality of the series of characters generated by inputting through the multi key among the series of characters generated by the Hangul combiner correspond to the word defined by the Hangul input assistance dictionary; and an output means for outputting the one with the highest output rank among the series of characters generated by the Hangul combiner to the information appliance and storing the rest with lower output ranks in a temporary storage.

To accomplish the above objects, according to one aspect of the present invention, there is also provided a method for expressing Hangul, which is used for inputting and outputting Hangul to an information appliance with an input means, the method comprising: a first step of combining jamos inputted by the input means to generate at least one series of characters including a syllable; a second step of deciding if the series of characters corresponds to series of characters defined by a Hangul word information dictionary; and a third step of outputting to the information appliance the series of characters with the highest output rank among series of characters corresponding to at least one syllable of the series of characters defined by the Hangul word information dictionary, and storing the rest with lower output ranks in a temporary storage, wherein the information appliance comprises the Hangul word information dictionary for defining series of characters including at least one syllable and adding grammar information to each of the defined series of characters.

To accomplish the above objects, according to one aspect of the present invention, there is also provided a method for expressing Hangul, which is used for inputting and outputting Hangul to an information appliance with an input means, the method comprising: a first step of combining jamos inputted by the input means to generate at least one series of characters including a syllable; a second step of deciding if the series of characters corresponds to series of characters defined by a Hangul word connection definition dictionary; and a third step of outputting to the information appliance the series of characters with the highest output rank among series of characters corresponding to at least one syllable of the series of characters defined by the Hangul word connection definition dictionary, and storing the rest with lower output ranks in a temporary storage, wherein the information appliance comprises the Hangul word connection definition dictionary for defining series of characters including at least one syllable and adding a list of words which can be connected to each of the defined series of characters so that each of the words can function grammatically.

To accomplish the above objects, according to one aspect of the present invention, there is also provided a method for expressing Hangul, which is used for inputting and outputting Hangul to an information appliance with an input means, the method comprising: a first step of combining jamos inputted by the input means to generate at least one series of characters including a syllable; a second step of deciding if the series of characters corresponds to a word defined by a Hangul word dictionary; and a third step of outputting to the information appliance the series of characters with the highest output rank among series of characters corresponding to at least one syllable of the word defined by the Hangul word dictionary, and storing the rest with lower output ranks in a temporary storage, wherein the information appliance comprises the Hangul word dictionary for defining words with at least one syllable and grammatical function.

To accomplish the above objects, according to one aspect of the present invention, there is also provided a method for expressing Hangul, which is used for inputting and outputting Hangul to an information appliance with an input means which comprises at least one multi key to which a plurality of consonants are assigned, the method comprising: a first step of combining jamos inputted by the input means to generate at least one series of characters including a syllable; a second step of deciding if a plurality of the series of characters generated by inputting through the multi key among the generated series of characters correspond to a word defined by a Hangul input assistance dictionary; and a third step of outputting to the information appliance the series of characters with the highest output rank among the series of characters which correspond to a word defined by the Hangul input assistance dictionary in the second step and storing the rest with lower output ranks in a temporary storage, wherein the information appliance comprises the Hangul input assistance dictionary for defining a word which has uncertainty in a boundary of series of characters among series of characters which are capable to be generated by inputting through the multi key.

To accomplish the above objects, according to one aspect of the present invention, there is also provided a method for expressing Hangul, which is used for inputting and outputting Hangul to an information appliance with an input means, the method comprising: a first step of combining jamos inputted by the input means to generate at least one series of characters including a syllable; a second step of deciding if the Hangul code of the generated series of characters is a completion-type/combination-type; a third step of converting the Hangul code of the series of characters which has been decided as the completion-type/combination-type to a Hangul jamo code; a fourth step of deciding if the series of characters correspond converted in the third step corresponds to a series of characters defined by a Hangul word information dictionary; a fifth step of converting the Hangul jamo code of the series of characters, which has been decided as corresponding to a series of characters defined by the Hangul word information dictionary, to a completion-type/combination-type; and a sixth step of outputting the series of characters converted in the fifth step to the information appliance, wherein the information appliance comprises the Hangul word information dictionary for defining series of characters including at least one syllable and adding grammar information to each of the defined series of characters. It is to be understood that both the foregoing general description and the following detailed description of the present invention are exemplary and explanatory and are intended to provide further explanation of the invention as claimed.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings;

FIG. 1a illustrates a Hangul alignment of a conventional terminal keypad, which is disclosed in the Korean registered Patent No. 159191;

FIG. 1b illustrates a Hangul alignment of a conventional terminal keypad, which is disclosed in the Korean registered Patent No. 291838;

FIG. 1c illustrates a Hangul alignment of a conventional terminal keypad, which is disclosed in the Korean publication No. 2004-61800;

FIG. 1d illustrates a Hangul alignment of a conventional terminal keypad, which is disclosed in the Korean registered Patent No. 421545;

FIG. 1e illustrates a Hangul alignment of a conventional terminal keypad, which Motorola Inc. uses for its mobile phones;

FIG. 1f illustrates a Hangul alignment of a conventional terminal keypad, which is disclosed in the Korean registered Patent No. 377432;

FIG. 2 illustrates a construction in accordance with a first embodiment of the present invention;

FIG. 3 illustrates an embodiment of a TRIE structure;

FIG. 4a shows an embodiment of a TRIE structure of a Hangul word information dictionary which uses the Hangul jamo code according to the Unicode Standard;

FIG. 4b shows an embodiment of a TRIE structure of a Hangul word information dictionary which uses the Hangul code system disclosed in the Korean Patent bulletin No. 1995-543;

FIG. 5 is a flow chart which shows a process for converting Hangul jamo codes, in accordance with an embodiment of the present invention;

FIG. 6a shows examples of grammar information in accordance with the first embodiment of the present invention;

FIG. 6b shows examples of series of characters paired with their grammar information, in accordance with the first embodiment of the present invention;

FIG. 7 shows a connection information table in accordance with an embodiment of the present invention;

FIG. 8 is a flow chart representing the first embodiment of the present invention;

FIG. 9 illustrates a construction in accordance with a second embodiment of the present invention;

FIG. 10 a flow chart representing the second embodiment of the present invention;

FIG. 11a shows an embodiment of a connection-possibility information table in accordance with the second embodiment of the present invention;

FIG. 11b shows another embodiment of a connection-possibility information table in accordance with the second embodiment of the present invention;

FIG. 12 illustrates a construction in accordance with a third embodiment of the present invention;

FIG. 13 a flow chart representing the third embodiment of the present invention;

FIG. 14 illustrates a construction in accordance with a fourth embodiment of the present invention; and

FIG. 15 a flow chart representing the fourth embodiment of the present invention.

### DETAILED DESCRIPTION OF THE PREFERRED EMBODIMENT

The present invention will now be described more fully with reference to the accompanying drawings, in which exemplary embodiments of the invention are shown. The invention may, however, be embodied in many different forms and should not be construed as being limited to the embodiments set force herein, rather, these embodiments are provided so that this disclosure will be thorough and complete, and will fully convey the concept of the invention to those skilled in the art.

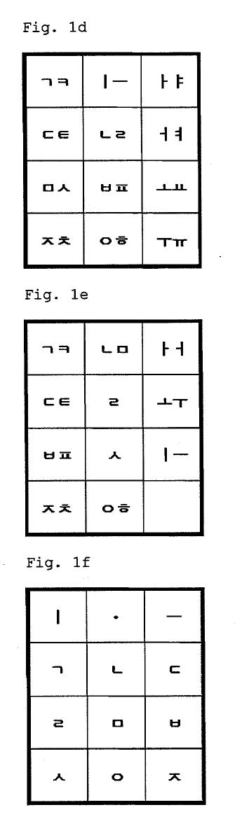

FIG. 2 illustrates a construction in accordance with a first embodiment of the present invention. Referring to FIG. 2, the apparatus for expressing Hangul according to the first embodiment of the present invention comprises a Hangul combiner 210, a Hangul word information dictionary 250, a character controller 220, an output means 230 and a connection information table 260. In inputting Hangul to an information appliance with an input means 200, the Hangul combiner 210 combines jamos inputted to the information appliance to generate at least one series of characters including a syllable. When jamos are inputted by multi-tapping (pressing or touching plurally) or single-tapping (pressing or touching once) a single key to which a single jamo is assigned or a multi key to which a plurality of jamos are assigned, the Hangul combiner 210 receives the inputted jamos as inputted series of characters and generates Hangul, which includes the series of characters corresponding to a syllable.

The Hangul combiner 210 generates a singular or plural series of characters when jamos are inputted through a multi key. At this time, letter information, which is required to classify inputted consonants to a chosung (initial letter) or jongsung (final letter) of a syllable, is generated with the series of characters. And then, the Hangul combiner 210 provides the generated series of characters to a character controller 220, in which the series of characters are compared to a series of characters found by searching a Hangul word information dictionary 250. At this time, the series of characters generated in the Hangul combiner is used as a search key for searching the series of characters defined by the Hangul word information dictionary 250.

For example, if [symbol] , [symbol] and [symbol] are plurally assigned to a key, [symbol] is inputted by pressing the key once, [symbol] is inputted by pressing the key twice, and [symbol] is inputted by pressing the key three times.

In case that a character generated by multi-tapping a multi key is used as a chosung of a first syllable, it is easy to tell which letter is intended among the letters which are assigned to the multi key. However, in case that such a character is to be used as a letter between characters, it is necessary to tell that the letter is a jongsung of a preceding syllable or a chosung of a following syllable. This is a linguistic problem which Hangul has because of its own structure. The Hangul combiner 210 of the present invention is used to solve such a problem.

For example, the Hangul jamos [symbol] are inputted to the Hangul combiner 210 of the present invention. In this case, the Hangul combiner 210 generates three series of characters, [symbol] , [symbol] and [symbol] , because the Hangul combiner 210 operates according to Hangul combination rules which make the jamos combine in that way if a user presses three times a key to which the jamos [symbol] are assigned.

The Hangul word information dictionary 250 defines series of characters including at least one syllable, and adds grammar information to each of the defined series of characters. The grammar information includes information about parts of speech for the series of characters, information about inflection of the series of character, information about a frequency of using the series of characters, etc.

The Hangul word information dictionary 250 is a kind of an electronic dictionary. The electronic dictionary is a general linguistic dictionary provided in an electronic form and processed by a computer, and it can be classified into a hash table type, B-TREE type, TRIE type, etc. The Hangul word information dictionary 250 according to the present invention is constructed in a TRIE type.

A TRIE is an ordered tree data structure that is used to store an associative array where the keys are usually strings. In a TRIE structure, all the descendants of any one node have a common prefix of the string associated with that node. And it is efficient in searching an inputted series of characters, on the basis of syllables given to strings, using a longest-key correspondence search or a prefix-only-correspondence search.

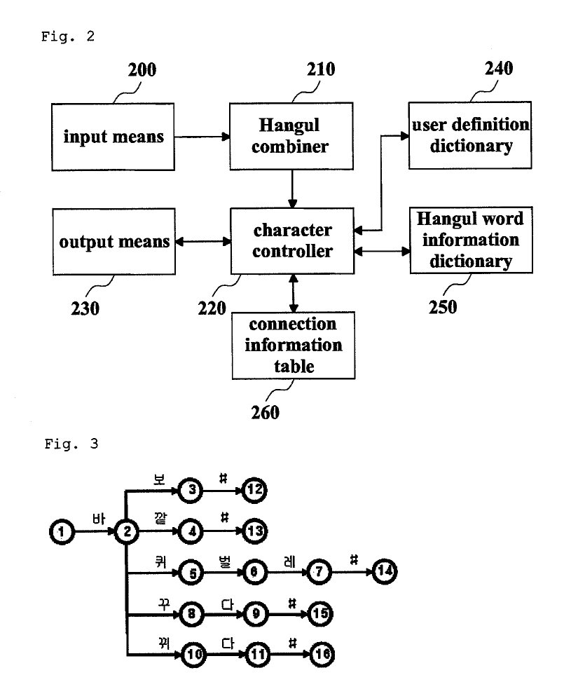

FIG. 3 shows an example of a TRIE structure for the Hangul key sets [symbol] , [symbol] , [symbol] , [symbol] , [symbol] and [symbol] }.

Referring to FIG. 3, in case of searching the key [symbol] , the initial node \textcircled{1} defines a transition to the node \textcircled{2} according to the transition character [symbol] , and this relation can be represented as the formula G(1, [symbol] )=2. And then, The transition G(2, [symbol] )=5 is made to search the key.

A transition character is defined as a character which causes a transition from one node to another, and all the transition characters are expressed in Hangul codes in a computer. As an international standard of Hangul codes, the Unicode system defines a combination type, a completion type and a jamo type. Among them, a combination type and a completion type are principally being used as a code for processing Hangul information, and these types express a character of Hangul as a unit in 2 bytes. The Unicode system is used as a standard for processing Hangul information, such as in inputting and outputting Hangul, in search engines or in electronic dictionaries.

The Hangul word information dictionary 250 according to the present invention employs a Hangul code which does not have a syllable but a jamo as a unit of a transition character between nodes of its TRIE structure. The reason for employing such Hangul code is as follows: If the Hangul word information dictionary with a TRIE structure is based on a combination type or completion type Hangul code, a transition unit between nodes of TRIE is a syllable, not a jamo. Since the series of characters generated in the Hangul combiner 210 include a jamo as well as a syllable, a syllable unit is required to be converted to a jamo unit as the occasions demand, so that the Hangul word information dictionary 250 can be searched on the basis of a combination type or completion type Hangul code. That is, in case of a Hangul word information dictionary using a Hangul code which has a syllable as a unit of a transition character, there is a problem of converting a transition unit from a syllable unit to a jamo unit or from a jamo unit to a syllable unit whenever searching the Hangul word information dictionary. In addition to this problem, there is a drawback of a lower efficiency in processing a whole search.

There are Hangul codes with a jamo unit, such as the Hangul jamo code of the Unicode and the Hangul code system of the Korean registered Patent No. 1995-543.

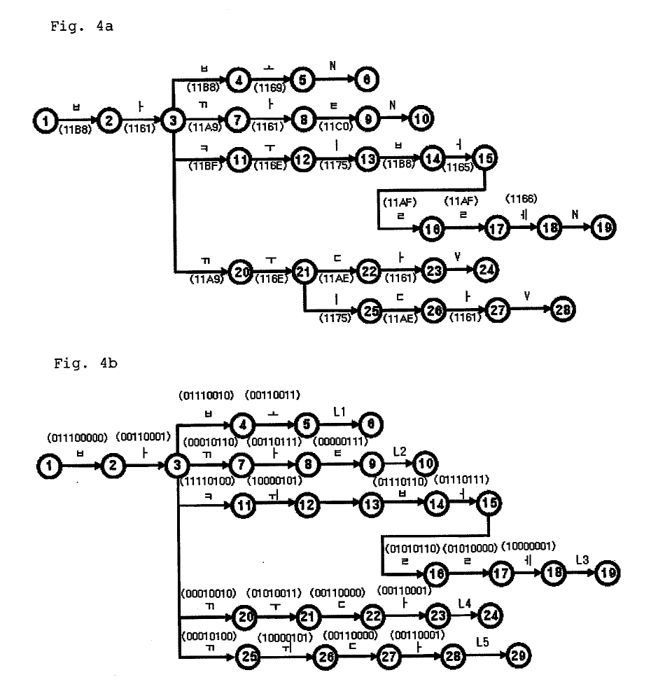

FIG. 4a shows an embodiment of a TRIE structure of a Hangul word information dictionary which uses the Hangul jamo code according to the Unicode Standard; and FIG. 4b shows an embodiment of a TRIE structure of a Hangul word information dictionary which uses the Hangul code system disclosed in the Korean Patent bulletin No. 1995-543.

In FIG. 4a, codes of transition characters are represented with a Hangul classification of chosung/jungsung (medial letter) or chosung/jungsung/jongsung. Transition characters in FIG. 4b are represented with Hangul characters classified into 6 types as shown below.

(1) the first type (consonant+vertical vowel: [symbol] , [symbol] , etc.)

(2) the second type (consonant+horizontal vowel: [symbol] , [symbol] , etc.)

(3) the third type (consonant+diphthong (combination of horizontal and vertical vowels): [symbol] , [symbol] , etc.)

(4) the fourth type (consonant+vertical vowel+consonant: [symbol] , [symbol] , etc.)

(5) the fifth type (consonant+horizontal vowel+consonant: [symbol] , [symbol] , etc.)

(6) the sixth type (consonant+diphthong (combination of horizontal and vertical vowels)+consonant: [symbol] , [symbol] , etc.)

It can be understood that the codes of FIG. 4b are made by extending the Hangul jamo codes of Unicode standard according to Hangul shapes. In the codes of FIG. 4b, each jamo takes one byte, and code values of transition characters between nodes of a TRIE structure make the values for these codes.

These code systems have the following advantages over a combination type or completion type code system. First, searching a dictionary in a unit of jamo can be made more easily because the code systems contain information about jamo elements constituting a character. Second, number of the key elements in these code systems can be reduced to the number of consonants which can be a chosung. That is, the prefixes of all the words can be represented with 15 key elements. On the contrary, number of key elements required for a combination type or completion type Hangul code is 2,500˜11,700. Accordingly, these code systems can be more efficient in searching than a combination type or completion type Hangul code. Third, a dictionary can be modified in a unit of jamo, thus more easily. In addition, these code systems may be applied to a next-generation user interface, since it is likely to fuse the code systems with a voice-recognition system.

The current standard types for inputting and outputting Hangul support a combination type code or a completion type code only. So, if a Hangul word information dictionary is realized with a Hangul editor which uses only the current standard codes, the advantages listed above can not be enjoyed. In other words, the current computer systems, which employ a combination type or completion type code for inputting and outputting Hangul, need a separate system for converting codes.

A process for searching the Hangul word information dictionary 250 is dependent on whether the series of characters generated in the Hangul combiner 210 is in a Hangul combination type or a completion type code, or a jamo type code. In case that the series of characters generated in the Hangul combiner 210 is a combination type or a completion type, if the Hangul word information dictionary 250 has a jamo type code, the dictionary is searched after conversion of the code of the series of characters to a jamo type code. And in case that the series of characters generated in the Hangul combiner 210 is in a jamo type, the dictionary is searched without code conversion.

As mentioned above, most of the computers used currently input and output Hangul by a combination/completion code. Accordingly, a system for converting a combination/completion code into a jamo code is required for the present invention to be applied to the existing information appliances.

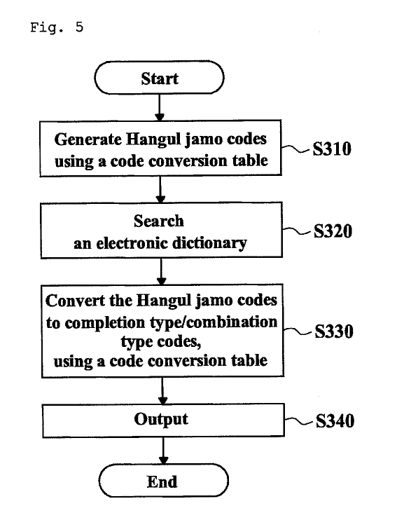

FIG. 5 is a flow chart which shows a process for converting Hangul codes, in accordance with an embodiment of the present invention. FIG. 5 shows a process in that Hangul generated by the current standard type code is converted to a Hangul jamo code, to be prepared for a word search.

The series of characters generated in the Hangul combiner 210 are transferred to a character controller 220, in which it is judged whether the transferred series of characters have a combination/completion type code or not. In case of a combination/completion type code, a code conversion program is used to generate a corresponding Hangul jamo code in S310. For converting a combination/completion type code to a jamo type code, it is preferred to use a code conversion table in which each combination/completion type code is made to correspond to its jamo type code.

And then, the character controller 220 searches the Hangul word information dictionary 250 in S320 to find corresponding series of characters using the generated Hangul jamo code. The series of characters found in the Hangul word information dictionary is converted to a combination/completion type code in S330 using the code conversion program which employs the code conversion table. After that, the series of characters are transferred to an output means and outputted in S340. The process for converting to a Hangul jamo code is preferably performed in the character controller 220. As described above, when a series of characters from the Hangul combiner 210 is inputted to the character controller 220, the character controller 220 decides if the inputted series of characters corresponds to any series of characters defined by the Hangul word information dictionary 250.

In a first embodiment according to the present invention, grammar information is added to the series of characters including at least one syllable, which is defined by the Hangul word information dictionary.

The grammar information includes parts of speech or conjugation types for the series of characters, i.e., words defined by the Hangul word information dictionary 250, and the grammar information is included for making each word function grammatically. The grammar information has a format for being actually registered in a dictionary, and is registered in the Hangul word information dictionary 250 along with the boundary of each word. The grammar information takes the following form:

(Korea (noun (1/N))).

The grammar information shows which part of speech the Hangul word inputted to the information appliance belongs to, namely, the information such as a noun, a pronoun, a preposition, an ending of a verb, etc. Interconnection information is also provided and used to indicate a boundary of a preceding word and a following word inputted continuously to the preceding word and to show how preceding and following words can be connected to each other from their relations.

Using the information, an intelligent system for inputting and outputting Hangul can be realized, which enables a correct sentence with a space to be outputted, though a space has not been inputted.

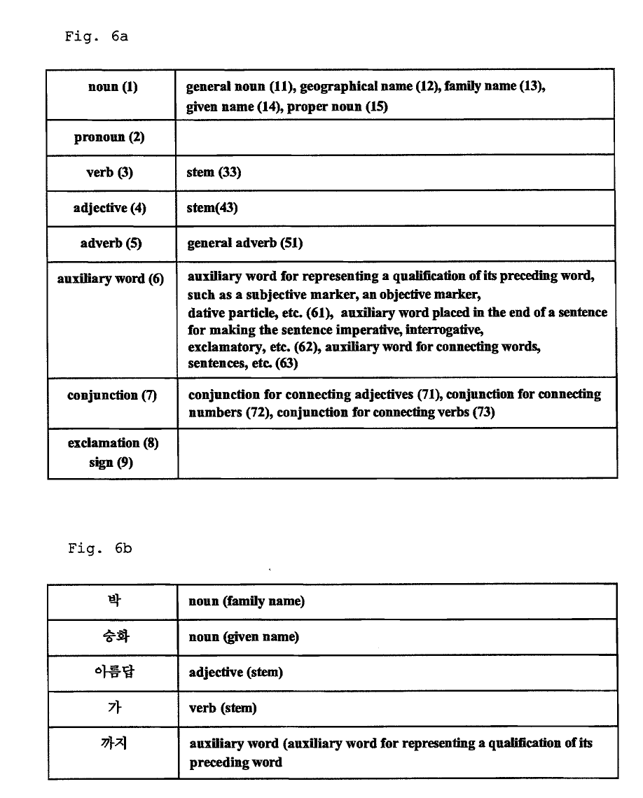

FIG. 6a shows examples of grammar information in accordance with the first embodiment of the present invention; and FIG. 6b shows examples of series of characters paired with their grammar information, in accordance with the first embodiment of the present invention.

Referring to FIG. 6a, for example, a noun inputted to the information appliance can be classified into categories such as a general noun, a geographical name, a family name and a given name. And the parts of speech such as a verb and an adjective can be inflected, and thus can be classified on the basis of the grammar information, for example, a stem of a word. The other parts of speech also can be standardized and classified with knowledge on the general Korean grammar.

The grammar information can be represented as a sign, such as ‘N’ or ‘V’ in the TRIE structure in FIG. 4a. Besides the grammar information, quantitative information, such as a frequency of use of a word can be added and used.

In the present invention, the grammar information for a word like a part of speech is represented in Hangul, but can be marked by a numeral or a sign, instead of Hangul. For example, 1(N) for a noun, 2(PN) for a pronoun, 3(AD) for a stem of an adjective, 4(V) for a stem of a verb, 5(PP) for an auxiliary word, etc. If the grammar information is represented as a numeral or a sign in this way, memory can be saved. And also, interconnection information about an interconnection between words can be simply marked with a numeral, and accordingly, a simple search can be made.

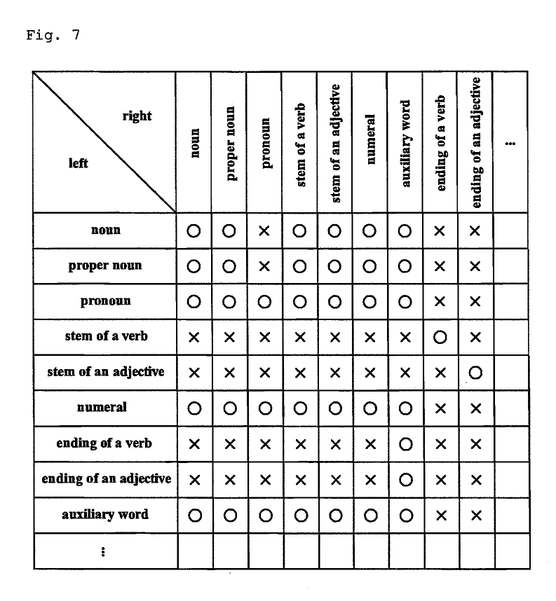

FIG. 7 shows a connection information table in accordance with an embodiment of the present invention.

In case that Hangul is continuously inputted to an information appliance, if an inputted preceding series of characters is searched to have a corresponding series of characters in a Hangul word information dictionary 250, the inputted preceding series of characters is recognized as a word. The word is outputted to the display means of the information appliance and also, the grammar information of the word is stored in a temporary store.

After that, a following series of characters inputted continuously to the preceding series of characters are searched in the Hangul word information dictionary 250. An apparatus for expressing Hangul judges if a preceding word and a following word can be connected to each other, when they are inputted and outputted completely. At this time, it is preferred to use a connection information table 260 such as one shown in FIG. 7.

Referring to FIG. 7, the connection information table 260, which is already stored in the apparatus for expressing Hangul, teaches that a noun can be connected to another noun, a stem of a verb, or a stem of an adjective.

For example, series of characters for the sentence [symbol] are inputted without spacing, i.e., in the form of [symbol] to the information appliance through the apparatus for expressing Hangul. In this case, the word corresponding to each word of the sentence and the grammar information for each word of the sentence are searched in the Hangul word information dictionary 250, and resultingly, the sentence correctly spaced between the words [symbol] is recognized and outputted.

The input and output processes for the sentence are described below. [symbol] is searched in the Hangul word information dictionary 250 to be found to be a word of which grammar information is a pronoun. Subsequently, [symbol] is searched to be a postposition (auxiliary word) in the Hangul word information dictionary 250. An auxiliary word can be connected to a pronoun in the order of a pronoun-an auxiliary word, so the connection between the two words [symbol] and [symbol] is judged as being correct.

In the same way, [symbol] is searched and then outputted as an adverb, [symbol] as the stem of the verb [symbol] , and [symbol] as an ending word which can be connected to a stem of a verb.

Like this, words which can be connected to each other are outputted in the connected form. And for words which can not be connected to each other, an automatic spacing is made between the words. Accordingly, inputting and outputting a correct sentence is guaranteed in spite of inputting series of characters without spacing. This enables sentences with spaces to be sent and received, especially for a mobile phone, to which letters are usually inputted without spacing.

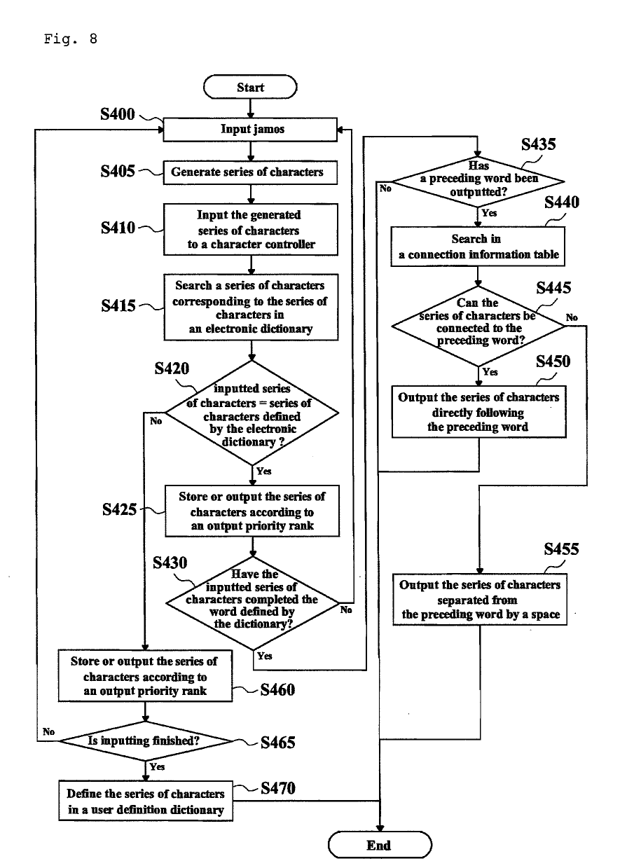

FIG. 8 is a flow chart representing the first embodiment of the present invention.

Referring to FIG. 8, Hangul is inputted to an information appliance, using an apparatus for expressing Hangul with an input means 200 comprising a key to which a plurality of jamos are assigned. The apparatus for expressing Hangul is set to a mode for inputting Hangul. When a user continuously inputs Hangul jamos to a Hangul combiner 210 in S400 through the input means 200 of the information appliance, a single series of Hangul characters or plural series of Hangul characters are generated in S405 according to the Hangul combination rule.

The generated series of characters are inputted to a character controller 220 in S410. The character controller 220 searches a Hangul word information dictionary 250 or a user definition dictionary 240 in S415 to find any word which corresponds to the inputted series of characters by comparing the inputted series of characters with the words in the dictionary in S420.

If the single or plural series of characters correspond to any one of the words defined by the Hangul word information dictionary 250 or the user definition dictionary 240, the corresponding series of characters are transferred to an output means 230.

The output means 230 outputs the series of characters with the highest output rank to a display means and stores the rest with lower output ranks in a temporary storage, according to a predetermined output rank, in S425. The temporary storage is preferably disposed in the output means 230, but not limited thereto.

The apparatus for expressing Hangul repeats the aforesaid processes until the inputted series of characters correspond to any word defined by the Hangul word information dictionary or the user definition dictionary, in S430.

If the inputted series of characters are found by the character controller 220 to match one of the words defined by the Hangul word information dictionary 250 or the user definition dictionary, the matched series of characters are determined to be outputted and they are stored in the temporary storage. The word to be outputted is the word that have been defined by the Hangul word information dictionary 250 or the user definition dictionary 240, and the word is stored in the temporary storage, with the grammar information which have been added to the word.

After that, the character controller 220 searches the temporary storage of the output means 230 to see if there is any word outputted prior to the word to be outputted, in S435. If there is a word outputted prior to the word to be outputted, a connection information table 260 is searched in S440 using the grammar information about the word to be outputted, wherein the grammar information is stored in the temporary storage. And it is decided whether the prior-outputted word can be connected to the word to be outputted in view of their grammar information, in S445.

The character controller 220 transfers the word to be outputted to the output means 230, along with the information regarding a possibility of connection of the words.

If the word to be outputted can be connected to the prior-outputted word, the output means 230 outputs the following word right after the prior-outputted word to the display means of the information appliance in S450. If the word to be outputted can not be connected to the prior-outputted word, the following word is outputted to the display means, with the word separated from the prior-outputted word by a space, in S455.

If there is no word outputted prior to the word to be outputted, the apparatus for expressing Hangul returns to the input mode and waits for a series of characters to be inputted.

In this way, it is guaranteed that the prior-outputted word and the following word to be outputted make a grammatically reasonable series of characters outputted to the display means. And also, the single output result can be guaranteed in a reasonable condition.

If the word corresponding to the series of characters generated in the character controller does not exist in the Hangul word information dictionary 250 or the user definition dictionary 240, the series of characters is probably a series of characters a user defines. In this case, the character controller 220 transfers to the output means 230 the series of characters which is not defined by the dictionaries and gets the transferred series of characters to be outputted to the display means in 460, according to a predetermined output priority rank. In addition, the series of characters are defined as a user definition word series.

According to the first embodiment of the present invention, it is confirmed through the character controller 220 that a single word or plural words corresponding to the generated series of characters are not defined by the Hangul word information dictionary 250 or the user definition dictionary 240. The words are simultaneously outputted to the display means through the output means 230 in S460. At this time, the output means 230 first outputs the word the user selects among the outputted words. If series of characters are continuously inputted, the apparatus for expressing Hangul returns to the input mode. If series of characters finishes being inputted in S465, the word outputted by the user's selection is registered in the user definition dictionary 240 in S470 through the character controller 220. And the apparatus for expressing Hangul waits for a next input. It is preferred that all the words registered in the user definition dictionary are defined as nouns, which are used as the grammar information for the words.

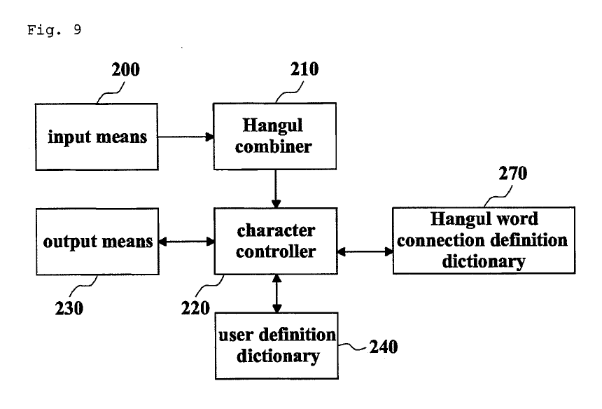

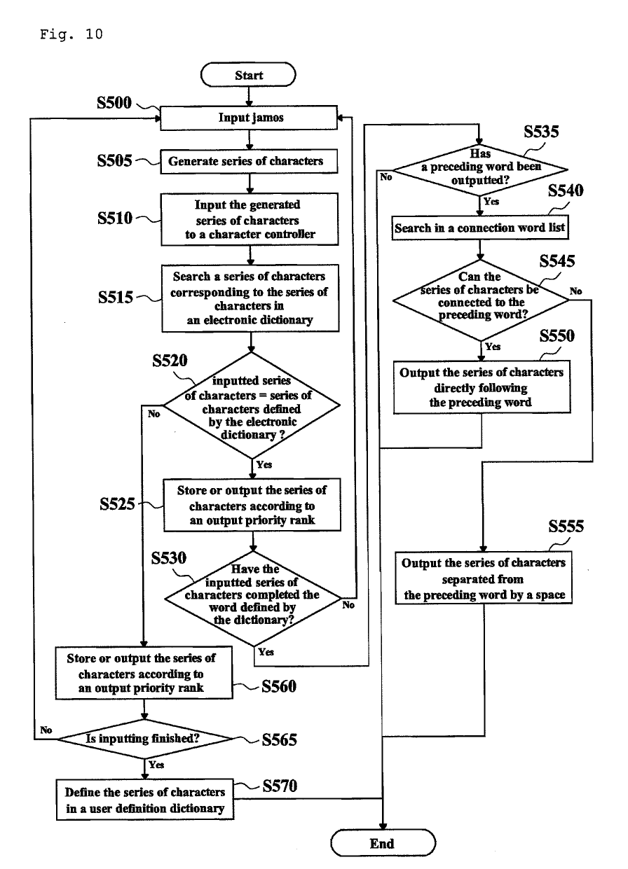

FIG. 9 illustrates a construction in accordance with a second embodiment of the present invention; and FIG. 10 a flow chart representing the second embodiment of the present invention.

Referring to FIG. 9 and FIG. 10, the apparatus for expressing Hangul in accordance with a second embodiment of the present invention comprises a Hangul combiner 210, a Hangul word connection definition dictionary 270, a character controller 220 and an output means 230. The Hangul combiner 210, the character controller 220 and the output means 230 in accordance with the second embodiment of the present invention have the functions similar to the corresponding components in accordance with the first embodiment of the present invention. However, the Hangul word connection definition dictionary 270 is realized in a different way from the Hangul word information dictionary 250.

The Hangul word connection definition dictionary 270 defines words including at least one syllable, and adds a list of words which can be connected to each of the defined words to make them function grammatically.

When a user continuously inputs Hangul jamos to the Hangul combiner 210 in S500, a single series of Hangul characters or plural series of Hangul characters are generated in S505 according to the Hangul combination rule.

The generated series of characters are inputted to the character controller 220 in S510. In S515 and S520, the character controller 220 searches the Hangul word connection definition dictionary 270 or the user definition dictionary 240 to find any word which corresponds to the inputted series of characters by comparing the inputted series of characters with the words in the dictionaries.

If the single or plural series of characters partly or wholly correspond to any one of the words defined by the Hangul word connection definition dictionary 270 or the user definition dictionary 240, the corresponding series of characters are transferred to an output means 230.

The output means 230 outputs the series of characters with the highest output rank to a display means and stores the rest with lower output ranks in a temporary storage, according to a predetermined output rank, in S525.

The apparatus for expressing Hangul repeats the aforesaid processes until the inputted series of characters correspond to any word defined by the Hangul word connection definition dictionary or the user definition dictionary, in S530.

If the inputted series of characters are to be found to completely match one of the words defined by the Hangul word connection definition dictionary or the user definition dictionary through search and comparison in the character controller 220, the matched series of characters are determined to be outputted and they are stored in the temporary storage, which is provided in the apparatus for expressing Hangul. The word to be outputted is the word that have been defined by the Hangul word connection definition dictionary 270 or the user definition dictionary 240, and the word is stored in the temporary storage, with a connection word list which have been added to the word.

After that, the character controller 220 searches the temporary storage of the output means to see if there is any word outputted prior to the word to be outputted, in S535. If there is a word outputted prior to the word to be outputted, the connection word list 260 is searched in S540 for the word to be outputted, wherein the connection word list is stored in the temporary storage. And it is decided whether the word to be outputted belongs to the connection word list, in other words, whether the word to be outputted can be connected to the prior-outputted word, in S545.

The character controller 220 transfers the word to be outputted to the output means 230, along with the information regarding a possibility of connection of the words.

If the word to be outputted can be connected to the prior-outputted word, the output means 230 outputs the following word right after the prior-outputted word to the display means of the information appliance in S550. If the word to be outputted can not be connected to the prior-outputted word, the following word is outputted to the display means, with the word separated from the prior-outputted word by a space, in S555.

Through such input/output process, just a single series of characters is outputted among a plurality of series of characters which could be outputted.

If there is no word outputted prior to the word to be outputted, the apparatus for expressing Hangul returns to the input mode and waits for a series of characters to be inputted.

If the word corresponding to the series of characters generated in the character controller does not exist in the Hangul word connection definition dictionary 270 or the user definition dictionary 240, the series of characters is probably a series of characters a user defines. In this case, the character controller 220 transfers to the output means 230 the series of characters which is not defined by the dictionaries, and gets the transferred series of characters to be outputted to the display means in 560, according to a predetermined output priority rank. In addition, the series of characters are defined as a user definition word series.

According to the second embodiment of the present invention, it is confirmed through the character controller 220 that a single word or plural words corresponding to the generated series of characters are not defined by the Hangul word connection definition dictionary 270 or the user definition dictionary 240. The words are simultaneously outputted to the display means through the output means 230 in S560. At this time, the output means 230 first outputs the word the user selects among the outputted words. If series of characters are continuously inputted, the apparatus for expressing Hangul returns to the input mode. If series of characters finishes being inputted in S565, the word outputted by the user's selection is registered in the user definition dictionary 240 in S570 through the character controller 220. And then, the apparatus for expressing Hangul waits for a next input.

According to the second embodiment of the present invention, the grammar information is not added to the Hangul word connection definition dictionary 270. Instead, a connection word list is added to the Hangul word connection definition dictionary 270, wherein the connection word list is a list of words which can be connected to a specific word to make the word function grammatically. If a matched word is found in the Hangul word connection definition dictionary 270 and outputted to the display means, it is decided if the word can be connected to a preceding word, using the connection word list.

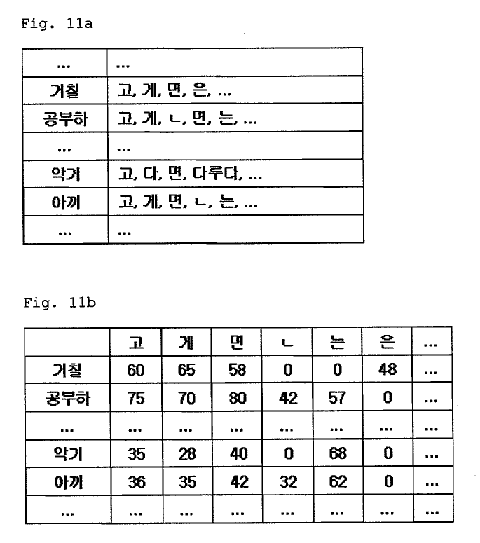

The connection word list can be made in a table, for example, as shown in FIG. 11a or FIG. 11b.

FIG. 11a shows an embodiment of a connection-possibility information table in accordance with the second embodiment of the present invention; and FIG. 11b shows another embodiment of a connection-possibility information table in accordance with the second embodiment of the present invention.

Referring to FIGS. 11a and 11b, a connection-possibility information table, which informs if a preceding word can be connected to a following word, can be thought as an electronic dictionary which is expressed in a matrix structure. Thus, it is more efficient to realize the connection-possibility information table in such a way that the words which can be connected to the word defined by the Hangul word connection definition dictionary can be defined with the word defined by the Hangul word connection definition dictionary, rather than to provide the connection-possibility information table separately from the Hangul word connection definition dictionary.

There is no need to input spaces in the method for expressing Hangul in accordance with the second embodiment of the present invention, either. This is because information about a boundary of each word, which is attained from the Hangul word connection definition dictionary 270, can be used. The Hangul word connection definition dictionary is an electronic dictionary, to which grammar information is not added separately. If series of characters are inputted, the Hangul word connection definition dictionary is searched to find a word which matches the inputted word. And the Hangul word connection definition dictionary provides information about which words can be connected next to the word which has been registered in the Hangul word connection definition dictionary. In this way, even though the Hangul word connection definition dictionary is not supplemented with grammar information, series of characters inputted without a space can be outputted as a sentence with a space.

Meanwhile, a connection strength value can be used in the second embodiment of the present invention, as shown in FIG. 11b. A connection strength value is defined as a quantitative value which indicates a strength with which a word can be connected to another word. Such a value can be used to represent grammatical function between words and increase accuracy for connection of words.

For example, if the words [symbol] and [symbol] are considered among words which can be connected next to the word [symbol] , the Hangul word connection definition dictionary 270 can be provided with the information that the connection strength of [symbol] is bigger than that of [symbol] and the information can be used for outputting words.

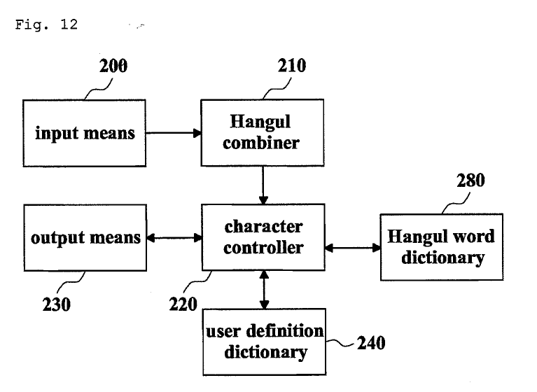

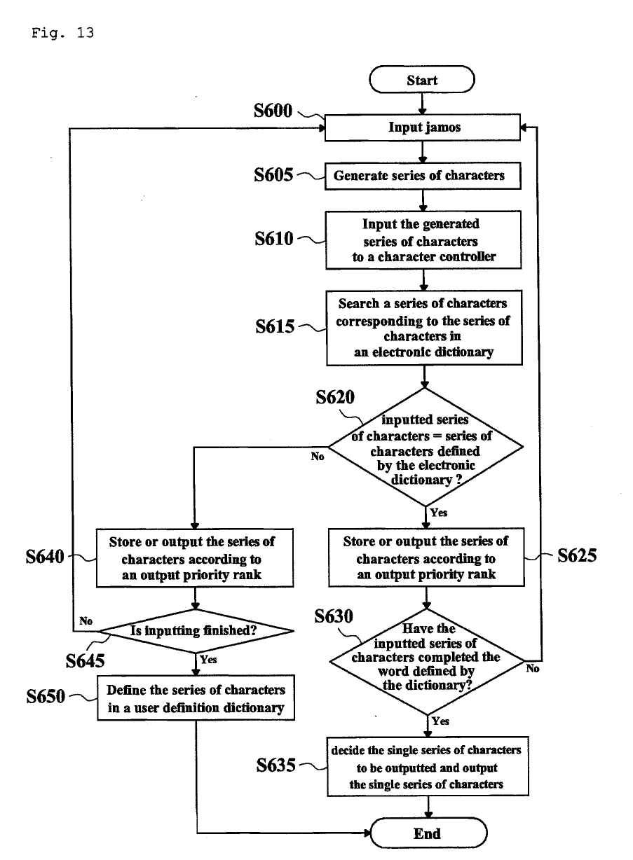

FIG. 12 illustrates a construction in accordance with a third embodiment of the present invention; and FIG. 13 a flow chart representing the third embodiment of the present invention.

Referring to FIG. 12 and FIG. 13, the apparatus for expressing Hangul in accordance with a third embodiment of the present invention comprises a Hangul combiner 210, a Hangul word dictionary 280, a character controller 220 and an output means 230. The Hangul combiner 210, the character controller 220 and the output means 230 in accordance with the third embodiment of the present invention have the functions similar to the corresponding components in accordance with the first embodiment and the second embodiment of the present invention. However, the Hangul word dictionary 280 is realized in a different way from the electronic dictionaries of the first embodiment and the second embodiment of the present invention.

The Hangul word dictionary 280 defines words which include at least one syllable and have grammatical functions.

When a user continuously inputs Hangul jamos to the Hangul combiner 210 in S600, a single series of Hangul characters or plural series of Hangul characters are generated in S605 according to the Hangul combination rule.

The generated series of characters are inputted to the character controller 220 in S610. In S615 and S620, the character controller 220 searches the Hangul word dictionary 280 or the user definition dictionary 240, using the inputted series of characters as a search key, to find any word which corresponds to the inputted series of characters by comparing the inputted series of characters with the words in the dictionary.

If the single or plural series of characters correspond to at least one syllable of the word(s) defined by the Hangul word dictionary 280 or the user definition dictionary 240, the corresponding series of characters are transferred to an output means 230.

The output means 230 outputs the series of characters with the highest output rank to a display means and stores the rest with lower output ranks in a temporary storage, according to a predetermined output rank, in S625.

The apparatus for expressing Hangul repeats the aforesaid processes until the inputted series of characters correspond to any word defined by the Hangul word dictionary or the user definition dictionary, in S630.

Through such input/output process, just a single series of characters is outputted among a plurality of series of characters which could be outputted.

If the word of the series of characters generated in the character controller does not exist in the Hangul word dictionary 280 or the user definition dictionary 240, the series of characters is probably a series of characters a user defines. In this case, the character controller 220 transfers to the output means 230 the inputted series of characters which is not defined by the dictionaries, and gets the transferred series of characters to be outputted to the display means in S640, according to a predetermined output priority rank. In addition, the series of characters are defined as a user definition word series.

According to the third embodiment of the present invention, it is confirmed through the character controller 220 that a single word or plural words corresponding to the generated series of characters are not defined by the Hangul word dictionary 280 or the user definition dictionary 240. The words are simultaneously outputted to the display means through the output means 230 in S640. At this time, the output means 230 first outputs the word the user selects among the outputted words. If series of characters are continuously inputted, the apparatus for expressing Hangul returns to the input mode. If series of characters finishes being inputted in S645, the word outputted by the user's selection is registered in the user definition dictionary 240 in S650 through the character controller 220. And then, the apparatus for expressing Hangul waits for a next input.

Meanwhile, the third embodiment of the present invention is very different from the first and second embodiments of the present invention in realizing an electronic dictionary. The Hangul word dictionary 280 in accordance with the third embodiment of the present invention is an electronic dictionary which does not have grammar information nor connection word list information. The Hangul word dictionary consists of words or phrases. Therefore, the Hangul word dictionary 280 is similar to the dictionaries of the first and second embodiments of the present invention in words without inflection, such as nouns, pronouns, auxiliary words, etc. However, for words with inflection, such as verbs and adjectives and so on, the Hangul word dictionary independently defines all the inflected types.

For example, the Hangul word dictionary 280 defines all the inflected types of the verb [symbol] , as shown below:

[symbol]

[symbol]

[symbol]

[symbol]

[symbol]

[symbol]

[symbol]

. . . .

That is, the Hangul word dictionary defines all the words above as independent words. This may cause a word to be repeated. But, thanks to this, the electronic dictionary can be realized easily, using a simple program for realizing the electronic dictionary.

The method for expressing Hangul according to the third embodiment of the present invention does not require series of characters to be inputted with a space, since the electronic dictionary can secure information about a boundary of a word or a phrase from a TRIE structure.

In addition, the information such as a frequency of use of each word or phrase or a history about recent inputs can be added to be used in input/output processes.

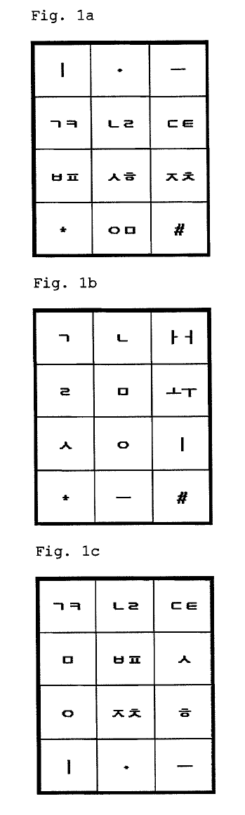

Hereinafter, it is shown that the embodiments of the present invention can be applied to the keypads of the mobile phones illustrated in FIGS. 1a-1f.

In case of a mobile phone of Samsung electronics of FIG. 1a, except for the jamos ‘Cheon Ji In’ ( [symbol] , [symbol] , [symbol] ) to be used for inputting vowels, all the consonants are plurally assigned to keys. Accordingly, when a user continuously inputs consonants assigned to a key, the consonants must be inputted with a time interval between inputs thereof or a function key must be used, to remove an ambiguity of key inputs.

The first embodiments and the second embodiment of the present invention are applied to the mobile phone of FIG. 1a, as follows.

The mobile phone has the multi keys, such as the number key 4 to which the jamos [symbol] are assigned, the number key 5 to which the jamos [symbol] are assigned, the number key 6 to which the jamos [symbol] are assigned, the number key 7 to which the jamos [symbol] , the number key 8 to which the jamos [symbol] are assigned, the number key 9 to which the jamos [symbol] are assigned, etc. First, the mobile phone is constituted to output a character specific to an input number of each of the multi keys, if a user continuously inputs or multi-taps one of the multi keys. Second, a Hangul combination rule is introduced to the mobile phone, so that a plurality of series of characters are generated through the Hangul combiner 210 as a multi key for a consonant and a single key for a vowel are inputted. Third, the mobile phone is equipped with the electronic dictionary embodying one of the Hangul word information dictionary 250, the Hangul word connection definition dictionary 270 and the Hangul word dictionary 280, according to each embodiment of the present invention, and the mobile phone is made to have a TRIE as its data structure. In addition, a transition character unit between nodes is a Hangul code system which has information of a chosung (initial letter), a jungsung (medial letter) or a jongsung (final letter). Fourth, an output priority rank is determined according to whether or not a word is defined by the electronic dictionary, or an order of recentness or frequency of use of a word.

If the first embodiment of the present invention is applied to the mobile phone of FIG. 1a constituted as described above, there is no need to use a function key or input a multi key with an interval between inputs.

For example, the words [symbol] , [symbol] , etc. are assumed to have been registered in the electronic dictionary. In this case, if [symbol] are inputted, the plural series of characters [symbol] and [symbol] are generated through the Hangul combiner 210. This is because that an ambiguity in a character boundary is caused by multi-tapping the key to which [symbol] and [symbol] are assigned.

The Hangul word information dictionary 250 is searched to find that both the plural series of characters are the part of the words defined by the Hangul word information dictionary 250. Subsequently, the series of characters are outputted to a display means of the mobile phone according the output priority rank. At this time, for example, the output priority rank is determined in the GaNaDa order, [symbol] is outputted prior to [symbol] . The plural series of characters do not make a complete word yet, the mobile phone is in the process for being inputted continuously.

And then, if [symbol] is inputted, the resulting series of characters [symbol] is found to complete a word defined by the electronic dictionary and accordingly, the output prior rank is changed to output [symbol] .

If the series of characters [symbol] are inputted continuously, [symbol] , which has been stored in the temporary storage as a series of characters with a posterior output rank, is changed into [symbol] , and thus [symbol] comes to have an output priority rank. And outputting for the series of characters inputted so far is performed.

The process as shown above can be applied to any one of the first, the second and the third embodiments of the present invention. The only difference in the embodiments of the present invention lies in the constitution of the electronic dictionary.

In case of the first embodiment of the present invention, at the time that the plural series of characters are recognized as a word defined by the electronic dictionary, the series of characters are stored in a designated buffer with the grammar information which has been added to the word. And at the time that a following word to be outputted is decided, word connection information is searched so that a single specific outputting of the two words can be made with a secured grammatical reasonability.

In case of the second embodiment of the present invention, the connection word list information can be used to have the same results. And in case of the third embodiment of the present invention, the same result can be made, if [symbol] and [symbol] are defined in the electronic dictionary, irrespective of their structures.

Moreover, as well as a TRIE, a Hangul transition character method using a jamo-type code system can be used in realizing the electronic dictionaries.

Next, in case of a mobile phone of LG electronics of FIG. 1b, a single consonant appears to be assigned to a single key. The consonants of similar shapes in a same series of consonants can be inputted by analogizing them using a separate function key. The vowels are assigned to multi keys and an input number is designated to each of the vowels.

If the embodiments of the present invention are applied to a mobile phone with this alignment, a time which it takes for a user to be accustomed to finding an appropriate function key on the basis of his analogy can be reduced. And the problems of a long distance of fingers' moving and a high degree of fatigue can be overcome. And also, the problem that the Hangul alignment is difficult to understand directly and immediately can be overcome.

In the Hangul alignment of mobile phones of LG Electronics, [symbol] are multiply assigned to a key and so can be inputted by single-tapping or multi-tapping the key.

Herein, for the first embodiment of the present invention to be applied to the mobile phones, a Hangul combination rule is provided. That is, multi-tapping for the key is defined to output [symbol] by pressing the key once, [symbol] by pressing the key twice, [symbol] by pressing the key three times, [symbol] by pressing the key four times, and [symbol] by pressing the key five times. If the process is performed as shown in the first embodiment of the present invention after the Hangul combiner is realized according to the Hangul combination rule, Hangul input and output without an ambiguity can be guaranteed.

For example, for inputting the word [symbol] , the key [symbol] is pressed four times continuously, one time for [symbol] and three times for [symbol] , after inputting [symbol] . The generated series of characters are [symbol] , [symbol] and [symbol] , among which [symbol] is outputted first according to the GaNaDa order. Through search in an electronic dictionary, [symbol] is stored in a buffer, a temporary storage and waits for a user's selection. If the word [symbol] has been registered in the dictionary, the series of characters [symbol] first begins to be outputted because it is a part of the word [symbol] , and a single outputting is performed as all the series of characters for the word are inputted.

There is no need to make any special structural changes when adding the components of the first, second and third embodiments of the present invention so as to solve the problems of the input method shown in the FIG. 1b. Further, there is no need for different or additional process in inputting vowels since a single outputting of a vowel is already guaranteed in the Hangul alignment of FIG. 1b.

In case of the Hangul input method of FIG. 1f, the multi keys, such as the number key 4 to which [symbol] are assigned, the number key 6 to which [symbol] are assigned, and the number key 9 to which [symbol] are assigned, are included, and thus a function key is introduced to input the consonants assigned to the multi keys. The need to use such a function key makes inputting troublesome.

The consonants assigned to the multi keys are inputted by multi-tapping the keys, for example, [symbol] by a first stroke of the number key 4, [symbol] by a second stroke and [symbol] by a third stroke, thereby causing an ambiguity in a character boundary in a word. This disadvantage can be overcome by checking whether a series of characters is a word registered in the electronic dictionaries of the embodiments of the present invention.

For example, the series of characters [symbol] are inputted, the plural series of characters [symbol] , [symbol] and [symbol] are generated through the Hangul combiner 210. After that, the electronic dictionary is searched to find the plural series of characters.

The series of characters [symbol] is probably for the word [symbol] , and the series of characters [symbol] is probably for [symbol] or [symbol] . Among them, the word [symbol] has been registered as a noun in the electronic dictionary. Therefore, the apparatus for expressing Hangul stores the corresponding word and its grammar information in a buffer and outputs the word according to the changed output priority rank.

In addition, the series of characters [symbol] , which has no possibility to form a Hangul word, is put to the temporary storage. The series of characters [symbol] and [symbol] are simultaneously outputted to the display means, and one of them is selected to be outputted according to a subsequently inputted series of characters. If the vowel [symbol] is inputted subsequently, [symbol] and [symbol] are outputted. [symbol] is outputted first between the two series of characters since [symbol] is found as a part of the word [symbol] in the electronic dictionary. On the other hand, [symbol] is stored in the temporary storage and waits for a user to input a next series of characters. [symbol] and [symbol] , which have been generated beforehand, do not have to be outputted simultaneously and one of them may be first outputted according to an output priority rank.

The embodiments of the present invention also can be applied to the Hangul input methods of FIG. 1c, FIG. 1d and FIG. 1e in the aforesaid ways, so as to overcome the disadvantages in inputting and outputting which the keypad alignments have.

Further, the embodiments of the present invention can be applied for inputting Hangul through a full keyboard of a computer. In this case, the series of characters assigned to multi keys can be inputted and processed without using a shift key.

In a computer keyboard, multi keys are used with a shift key to input the consonants [symbol] and the vowels [symbol] . If the first, second and third embodiments of the present invention are applied to such a computer keyboard, a system can be realized in which the jamos assigned to the multi keys can be inputted by single-tapping or multi-tapping the multi keys without using a shift key and the jamos to be outputted are automatically selected.

First, it is defined to input and output [symbol] , [symbol] , [symbol] , [symbol] or [symbol] , if a user presses the Hangul automata key [symbol] , [symbol] , [symbol] , [symbol] or [symbol] continuously two times for a chosung of a first syllable, and input and output both the jamos assigned to each of the keys, if a user does it for a chosung of a following syllable or a jongsung. In this case, a plurality of series of characters are generated, and accordingly it is preferred to build an electronic dictionary covering all the words which can be made with the plurality of series of characters.

Again, there is no problem in case of inputting a chosung of a first syllable through a multi key. However, for example, a Hangul combination rule can be provided to output [symbol] if [symbol] are inputted, and output [symbol] and [symbol] simultaneously if [symbol] are inputted.

The electronic dictionary in accordance with the embodiments of the present invention is constructed such that the electronic dictionary can include the words which have [symbol] , [symbol] , [symbol] , [symbol] or [symbol] as a jongsung of a syllable and [symbol] , [symbol] , [symbol] , [symbol] or [symbol] as a chosung of a next syllable, and the words which have [symbol] , [symbol] , [symbol] , [symbol] or [symbol] as a chosung of a syllable with no jongsung in a preceding syllable. There are only a few of the words which have such jamo characteristics in Hangul, enabling the electronic dictionary to be realized with ease.

As another example, the series of characters [symbol] are inputted. In this case, the plural series of characters [symbol] and [symbol] are simultaneously generated, and the electronic dictionary is searched for the plural series of characters.

Since the series of characters [symbol] and [symbol] are already defined by the electronic dictionary, one of the two series of characters is outputted first according to an output priority rank. If the output priority rank is decided in the GaNaDa order, [symbol] is made to be outputted first, and if the output priority rank is decided in the order of frequency of use, [symbol] is made to be outputted first.

Both the series of characters are parts of words, and inputting of subsequent series of characters is performed continuously. If the series of characters [symbol] are inputted subsequently, it becomes difficult to perform a single outputting. Just in such a case, a user selects one of the series of characters. In this way, a Hangul computer keyboard with no use of a shift key can be realized. For reference, [symbol] and [symbol] , [symbol] and [symbol] , and [symbol] and [symbol] are the examples of the very few words which make a single outputting difficult.

Meanwhile, there is no need to perform a special process in inputting Hangul vowels through the aforesaid keypads with keys to which a plurality of vowels are assigned. This is because vowels do not cause such an ambiguity as consonants do, in the Hangul structure.

The keypad-type Hangul alignments shown in FIGS. 1a-1f are the representative models and systems which have been commercialized currently. These Hangul alignments can be said to have the following common grounds:

In these Hangul alignments, except for the Hangul alignment of FIG. 1b, the Hangul consonants \textcircled{1} [symbol] , \textcircled{2} [symbol] , \textcircled{3} [symbol] , and \textcircled{4} [symbol] are assigned to four keys, and the tap orders for inputting each of the consonants are also same among these Hangul alignments. In addition, the consonants \textcircled{5} [symbol] , \textcircled{6} [symbol] , \textcircled{7} [symbol] , \textcircled{8} [symbol] , \textcircled{9} [symbol] , \textcircled{10} [symbol] , \textcircled{11} [symbol] , etc. are inputted and outputted in the similar ways.

To the Hangul alignment of FIG. 1b, in which [symbol] , [symbol] , [symbol] and [symbol] seem to be plurally assigned to the keys, can the embodiments of the present invention be applied, too.

Since the Hangul vowels do not cause an ambiguity when inputted, a system can be realized to be applied to all the Hangul alignments of FIG. 1a-1f, in consideration of the consonant parts thereof. A fourth embodiment of the present invention shows such a system.

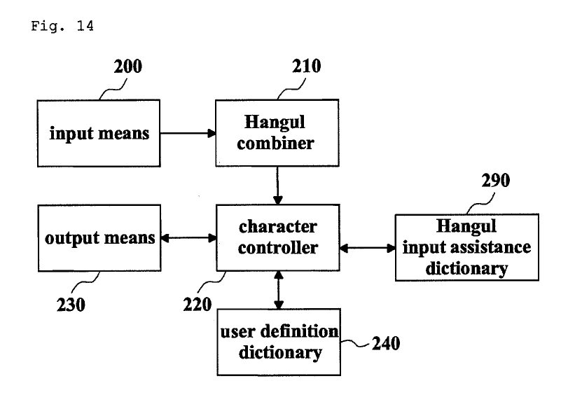

FIG. 14 illustrates a construction in accordance with the fourth embodiment of the present invention. Referring to FIG. 14, the apparatus for expressing Hangul in accordance with the fourth embodiment of the present invention comprises a Hangul combiner 210, a Hangul input assistance dictionary 290, a character controller 220 and an output means 230. The Hangul combiner 210, the character controller 220 and the output means 230 in accordance with the fourth embodiment of the present invention have the functions similar to the corresponding components in accordance with the other embodiments of the present invention. However, the Hangul input assistance dictionary 290 is realized in a different way from the dictionaries of the other embodiments of the present invention.

First, the words to be defined or registered in the Hangul input assistance dictionary 290 are collected. An ambiguity in inputting and outputting series of characters is caused by multi-tapping a key to which a plurality of characters are assigned. Accordingly, the series of characters with such an ambiguity are collected in the input methods of the mobile phones and defined as elements of the words in the electronic dictionary.

For example, for the Hangul alignments of FIGS. 1a, 1c, 1d, 1e, and 1f, the following series of characters are required to be defined:

\textcircled{1} all the words in which the first syllable has [symbol] [symbol] [symbol] as its chosong;

\textcircled{2} all the words in which a preceding syllable has no jongsung and a following syllable has [symbol] [symbol] [symbol] or [symbol] as its chosung;

\textcircled{3} all the words in which a jongsung of a preceding syllable/a chosung of a following syllable is [symbol] , [symbol] , [symbol] , [symbol] , [symbol] , [symbol] , [symbol] , [symbol] , [symbol] , [symbol] , [symbol] , [symbol] , [symbol] , [symbol] , [symbol] , [symbol] , [symbol] or [symbol] between vowels; and

\textcircled{4} all the words in which a syllable has [symbol] , [symbol] or [symbol] as its jongsong.

Besides, for the Hangul alignment of FIG. 1b, the following series of characters are required to be defined:

\textcircled{1} all the words in which the chosung of the first syllable is [symbol] or [symbol] ;

\textcircled{2} all the words in which a preceding syllable has no jongsung and a following syllable has [symbol] or [symbol] as its chosung; and

\textcircled{3} all the words in which a jongsung of a preceding syllable/a chosung of a following syllable is [symbol] , [symbol] , [symbol] , [symbol] , [symbol] , [symbol] , [symbol] , [symbol] , [symbol] , [symbol] , [symbol] , [symbol] , or [symbol] .

The Hangul input assistance dictionary 260, the electronic dictionary in accordance with the fourth embodiment of the present invention, is realized with the aforesaid words defined therein. Of course, some word elements can be deleted or added according to the Hangul alignments of mobile phones.

The Hangul input assistance dictionary 290 is realized in a different way from the electronic dictionaries of the first, second, and third embodiments of the present invention. The electronic dictionaries of the first, second, and third embodiments of the present invention are realized with all the words of Hangul as word elements of the electronic dictionaries. On the contrary, the electronic dictionary of the fourth embodiment of the present invention is constituted with only the words with the ambiguity, which can be caused by multi-tapping a multi key.

In other word, according to the fourth embodiment of the present invention, the Hangul input assistance dictionary 290 defines only the word elements which are necessary and sufficient to make a multiple outputting into a single outputting, thus providing an economical and efficient system.

In the meantime, if needed, information about a word element can be added to the Hangul input assistance dictionary 290, in the same way as the first and second embodiments of the present invention.

That is, like the electronic dictionary of the first embodiment of the present invention, after the words collected and defined in the Hangul input assistance dictionary 290 are divided into the smallest units which have meanings and grammatical functions, grammar information can be added to each of the divided words.

For example, the grammar information that [symbol] is a noun can be added to the electronic dictionary. And in case of the word [symbol] , the grammar information that [symbol] is a stem of a verb and [symbol] is an ending for conjunction can be added to the electronic dictionary, after [symbol] is divided to [symbol] and [symbol] .

In this way, the Hangul input assistance dictionary 290 can use the method for embodying the electronic dictionary of the first embodiment of the present invention, so that a correct outputting can be performed from more precise grammar information.

In addition, the method for embodying the electronic dictionary of the second embodiment of the present invention can be applied to the Hangul input assistance dictionary 290. That is, after the words collected and defined in the Hangul input assistance dictionary 290 are divided, and a word list, which can be added to each of the resulting words instead of grammar information, is extracted, the Hangul input assistance dictionary 290 can be realized and used in the same way as the electronic dictionary of the second embodiment of the present invention.

Of course, the method for embodying the electronic dictionary of the third embodiment of the present invention also can be applied to the Hangul input assistance dictionary 290 of the fourth embodiment of the present invention.

Besides, like the first, second and third embodiments of the present invention, a TRIE structure and a Hangul code system, and so on can be applied to the Hangul input assistance dictionary 290 of the fourth embodiment of the present invention.

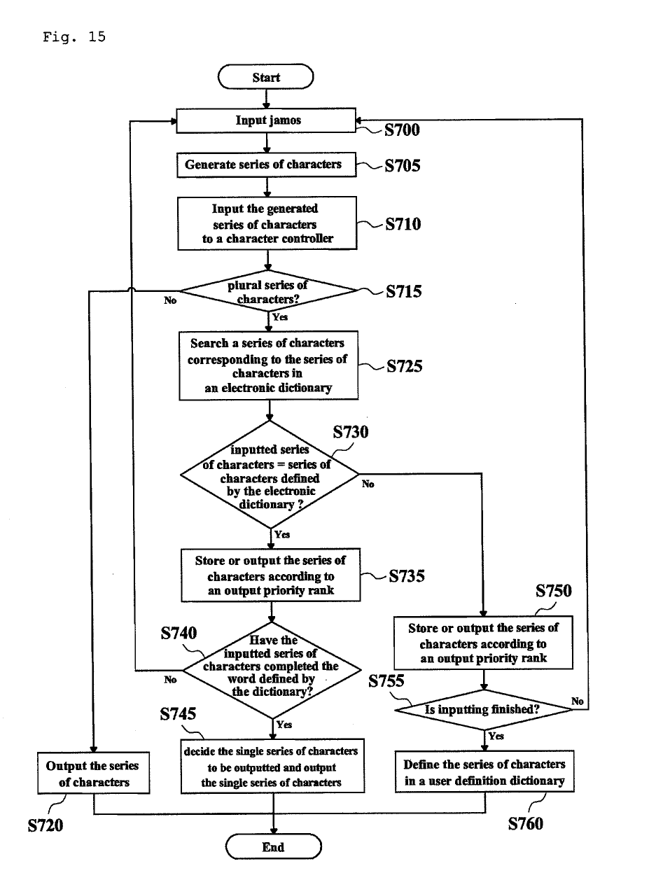

FIG. 15 a flow chart representing the fourth embodiment of the present invention. Referring to FIG. 15, the apparatus for expressing Hangul including a multi key in accordance with the fourth embodiment of the present invention is operated after a Hangul input mode is designated thereto. If a user continuously inputs Hangul jamos to a Hangul combiner 210 in S700, a single series of characters or a plurality of series of characters are generated in S705, according to the Hangul combination rule.

The generated series of characters are inputted to a character controller 220 in S710. If a single series of characters is inputted in S715, the character controller 220 transfers the series of characters to an output means 230 to make them directly outputted to a display means in S720, without intervening processes like a search process of an electronic dictionary. If a plurality of series of characters are inputted in S715, a Hangul input assistance dictionary 290 or a user definition dictionary 240 is searched by comparing the series of characters with words defined by the dictionary to find if the series of characters correspond to any of the words defined by the dictionary, in S725 and S730.

If the series of characters correspond to a word registered in the electronic dictionary, the character controller 220 transfers the word to the output means 230. The output means 230 first outputs the transferred word to the display means on the information appliance, according to the output priority rank, and stores words with lower priority ranks in a temporary storage, in S735.

On the other hand, if the words corresponding to the series of characters have not been registered in the electronic dictionary, the character controller 220 outputs the series of characters to the display means in S750, through the output means 230.

The apparatus for expressing Hangul repeats the aforesaid processes until the inputted series of characters correspond to any word defined by the electronic dictionary, in S740.

If a word reaches its end, the character controller 220 determines the inputted series of characters as a single series of characters, and makes the series of characters outputted to the display means of the information appliance in S745, through the output means 230.

In addition, if the outputted series of characters is not a word defined by the electronic dictionary, the character controller 220 confirms the ending of the inputting for the series of characters in S755, and then registers the series of characters in the user definition dictionary 240 in S760 according to a user's selection. And the apparatus for expressing Hangul returns to a state for a series of characters to be inputted.

At this time, grammar information or a connection word list can be added to the series of characters, by applying the first or second embodiment of the present invention.

The fourth example of the present invention can be applied in the environments of various mobile phones, as follows.

For example, [symbol] is processed in the environment shown in FIG. 1a, to which the fourth embodiment of the present invention is applied. In this case, [symbol] makes a single series of characters and thus it is outputted to the display means. And then, as soon as [symbol] is inputted, the plural series of characters, [symbol] and [symbol] are generated, and the electronic dictionary is searched.

Since [symbol] is one of the words registered in the electronic dictionary, [symbol] is outputted to the display means with a prior rank and [symbol] , which has a posterior rank, is stored in the temporary storage. At this time, the series of characters with a posterior rank can be outputted to the display means, or it can be stored in the temporary storage without being outputted.

Subsequently, [symbol] is inputted to generate [symbol] . [symbol] , an ending word which can be connected to [symbol] , is outputted to the display means. Back to the input mode, [symbol] and then [symbol] are inputted. Since both [symbol] and [symbol] make single series of characters inputted by single-tapping, they are outputted to the display means.

As [symbol] are inputted, the plural series of characters [symbol] and [symbol] are generated and searched to be found as word series registered in the electronic dictionary. Accordingly, the series of characters are outputted to the display means. At this time, if the series of characters [symbol] has a prior output rank, [symbol] is outputted first and [symbol] is stored as a series of characters with a posterior output rank.

As the subsequent series of characters [symbol] are inputted to make a complete word [symbol] , the word [symbol] is outputted to the display means. Back to the input mode, [symbol] is inputted, and the single series of characters [symbol] is outputted. The series of characters [symbol] , which is subsequently inputted, is determined to be outputted as a single series of characters. This finishes the input processes.

The fourth example of the present invention also can be applied in the environments of mobile phones of FIG. 1b, to realize more efficient apparatus for expressing Hangul. There is nothing but more complicated processes because more ambiguities by multi-tapping results from more multiple assignments.

Inputting and outputting of [symbol] is given as an example, in which the fourth example of the present invention is applied to the environment of mobile phones of FIG. 1d.

The series of characters [symbol] is outputted the display means as a single series of characters because it is inputted by single-tapping. At the moment that the subsequent [symbol] is inputted, the plural series of characters [symbol] and [symbol] are generated. Both of the series of characters are outputted to the display means since they are not the word series registered in the electronic dictionary. If [symbol] , which is inputted by single-tapping, is set to have a output rank prior to [symbol] , which is inputted by multi-tapping, [symbol] is outputted. As the subsequent characters of series [symbol] are inputted, [symbol] and [symbol] are generated. The series of characters [symbol] , a series registered in the electronic dictionary, is outputted to the display means. The resulting series of characters, [symbol] is determined to be outputted as a single series of characters. The aforesaid processes are repeated to input and output the subsequent series of characters.

Meanwhile, efficiency in inputting and outputting keys depends on input accuracy or input speed, etc.

A means for input-prediction can be added to the first to the fourth embodiments of the present invention, to improve efficiency in inputting keys. The means for input-prediction is used for predicting what series of characters to be inputted and outputting the series of characters.

The function of input-prediction can be added for completing a word when it is detected that the word is not completed in the process of detecting if a word is completed or not. In this way, additional functions for improving an input efficiency can be realized in the first to the fourth embodiments of the present invention.

In other words, the series of characters inputted and outputted in the present invention is a part of a word or a phrase which a user intends to input, and such a part of series of characters always can be detected in the TRIE structure of the electronic dictionary. Accordingly, a complete word or phrase defined by the electronic dictionary can be outputted in advance, although a user has not inputted all the series of characters for the word or phrase.

For example, if inputting and outputting of [symbol] has been determined up to now in the TRIE structure of FIG. 4a, the pointers for the outputted series of characters are in the nodes \textcircled{1}, \textcircled{2}, \textcircled{3}, \textcircled{11}, \textcircled{12}, and \textcircled{13}, in the electronic dictionary. In this case, the series [symbol] is the last part of the word registered in the electronic dictionary. The means for input-prediction can be used for automatically searching and outputting the word including the last part which has not yet inputted. In this way, an apparatus for expressing Hangul has an effect of predicting and outputting series of characters which follow series of characters inputted up to now. This can reduce number of a user's key inputting for following series of characters, thus improving an input efficiency.

The fourth embodiment of the present invention can be also applied to the environment for inputting Hangul using a full key set of a computer keyboard, to get a result similar to that made with the first to the third embodiments of the present invention.

In the meantime, output priority ranks for the embodiments of the present invention can be defined and used in various ways, for example, a GaNaDa order of series of characters, an order of recentness of input and output of series of characters, an order of frequency of use of series of characters, a priority order in the electronic dictionary, and a priority order in the user definition dictionary 240. Series of characters with the highest output priority rank are outputted first, and ones with lower output priority ranks are stored in other buffer. An output priority rank can be changed according to a change in conditions, so that series of characters with the highest output priority rank in a new condition can be outputted to the display means.

The foregoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

1. An apparatus for expressing Hangul, which is used to input and output Hangul to an information appliance, the apparatus comprising:
a Hangul combiner for distinguishing consonants of inputted jamos (consonants or vowels) into a chosung and a jongsung, and combining the inputted jamos to generate at least one series of characters including a syllable;
a Hangul word information dictionary for defining series of characters including at least one syllable, and adding grammar information to each of the defined series of characters including at least one syllable;
a character controller for deciding if the series of character generated by the Hangul combiner correspond to the series of characters defined by the Hangul word information dictionary;
an output means for outputting the one with the highest output rank among the series of characters generated by the Hangul combiner to the information appliance and storing the rest with lower output ranks in a temporary storage; and
a connection information table for providing connection information to decide if the series of character outputted to the information appliance can be connected to a next-inputted series of characters using the grammar information of the series of characters.

2. The apparatus of claim 1, further comprising:
a user definition dictionary for storing and managing the series of characters generated by the Hangul combiner with its grammar information, when it corresponds to none of the series of characters defined by the Hangul word information dictionary.

3. The apparatus of claim 1, wherein the grammar information is information regarding parts of speech for series of characters.

4. The apparatus of claim 3, wherein the information regarding parts of speech for series of characters is represented as a number or a sign.

5. The apparatus of claim 3, wherein the Hangul word information dictionary is realized on a basis of a TRIE structure.

6. The apparatus of claim 5, wherein a transition unit between nodes is a syllable unit or a Jamo unit, in the TRIE structure.

7. The apparatus of claim 6, wherein the output rank is decided according to at least one of a GaNaDa order of the series of characters, an order of recentness of input or output of the series of characters, an order of frequency of use of the series of characters, a priority order in the Hangul word information dictionary, and a priority order in the user definition dictionary.

8. An apparatus for expressing Hangul, which is used to input and output Hangul to an information appliance, the apparatus comprising:
a Hangul combiner for combining inputted jamos to generate at least one series of characters including a syllable;
a Hangul word connection definition dictionary for defining words including at least one syllable, and adding a list of words which can be connected to each of the defined words to make them function grammatically;
a character controller for deciding if the series of character generated by the Hangul combiner correspond to the series of characters defined by the Hangul word connection definition dictionary; and
an output means for outputting the one with the highest output rank among the series of characters generated by the Hangul combiner to the information appliance and storing the rest with lower output ranks in a temporary storage.

9. The apparatus of claim 8, further comprising:
a user definition dictionary for storing and managing the series of characters generated by the Hangul combiner, when it corresponds to none of the series of characters defined by the Hangul word connection definition dictionary.

10. The apparatus of claim 8, wherein the output rank is decided according to at least one of a GaNaDa order of the series of characters, an order of recentness of input or output of the series of characters, an order of frequency of use of the series of characters, a priority order in the Hangul word connection definition dictionary, and a priority order in the user definition dictionary.

11. The apparatus of claim 10, wherein the Hangul word connection definition dictionary indicates a connection strength between words as a numerical value.

12. An apparatus for expressing Hangul, which is used to input and output Hangul to an information appliance, the apparatus comprising:
a Hangul combiner for combining inputted jamos to generate at least one series of characters including a syllable;
a Hangul word dictionary for defining a word which includes at least one syllable and functions grammatically;
a character controller for deciding if the series of characters generated by the Hangul combiner correspond to the word defined by the Hangul word dictionary; and
an output means for outputting the one with the highest output rank among the series of characters generated by the Hangul combiner to the information appliance and storing the rest with lower output ranks in a temporary storage.

13. The apparatus of claim 12, further comprising:
a user definition dictionary for storing and managing the series of characters generated by the Hangul combiner, when it corresponds to none of the series of characters defined by the Hangul word dictionary.

14. The apparatus of claim 12, wherein the output rank is decided according to at least one of a GaNaDa order of the series of characters, an order of recentness of input or output of the series of characters, an order of frequency of use of the series of characters, a priority order in the Hangul word dictionary, and a priority order in the user definition dictionary.

15. An apparatus for expressing Hangul, which is used to input and output Hangul to an information appliance using an input means with at least one multi key to which a plurality of consonants are assigned, the apparatus comprising:
a Hangul combiner for combining inputted jamos to generate at least one series of characters including a syllable;
a Hangul input assistance dictionary for defining a word which has uncertainty in a boundary of series of characters among series of characters which are capable to be generated by inputting through the multi key;
a character controller for deciding if a plurality of the series of characters generated by inputting through the multi key among the series of characters generated by the Hangul combiner correspond to the word defined by the Hangul input assistance dictionary; and
an output means for outputting the one with the highest output rank among the series of characters generated by the Hangul combiner to the information appliance and storing the rest with lower output ranks in a temporary storage.

16. The apparatus of claim 15, wherein the output means outputs a syllable which can be generated by inputting through a single key to which a single jamo is assigned or inputting discontinuously through the multi key, irrespective of correspondence in the character controller.

17. The apparatus of claim 16, further comprising:
A user definition dictionary for storing and managing the series of characters generated by the Hangul combiner, when it corresponds to none of the words defined by the Hangul input assistance dictionary.

18. The apparatus of claim 15, wherein the output rank is decided according to at least one of a GaNaDa order of the series of characters, an order of recentness of input or output of the series of characters, an order of frequency of use of the series of characters, a priority order in the Hangul input definition dictionary, and a priority order in the user definition dictionary.

19. A method for expressing Hangul, which is used for inputting and outputting Hangul to an information appliance with an input means, the method comprising:
a first step of combining jamos inputted by the input means to generate at least one series of characters including a syllable;
a second step of deciding if the series of characters corresponds to series of characters defined by a Hangul word information dictionary; and
a third step of outputting to the information appliance the series of characters with the highest output rank among series of characters corresponding to at least one syllable of the series of characters defined by the Hangul word information dictionary, and storing the rest with lower output ranks in a temporary storage,
wherein the information appliance comprises the Hangul word information dictionary for defining series of characters including at least one syllable and adding grammar information to each of the defined series of characters.

20. The method of claim 19, further comprising:
a fourth step of deciding if a first series of characters outputted in the third step can be connected to a second series of characters inputted just after the first series of characters; and
a fifth step of outputting the second series of characters to the information appliance, if the second series of characters can be connected to the first series of characters.

21. The method of claim 20, wherein it is decided, in the fourth step, if the first series of characters can be connected to the second series of characters in the respect of their grammar information.

22. The method of claim 21, wherein the grammar information is information regarding parts of speech for series of characters.

23. The method of claim 22, wherein the information regarding parts of speech for series of characters is represented by a number or a sign.

24. The method of claim 19, wherein the Hangul word information dictionary is realized on a basis of a TRIE structure.

25. The method of claim 24, wherein a transition unit between nodes is a syllable unit or a Jamo unit, in the TRIE structure.

26. A method for expressing Hangul, which is used for inputting and outputting Hangul to an information appliance with an input means, the method comprising:
a first step of combining jamos inputted by the input means to generate at least one series of characters including a syllable;
a second step of deciding if the series of characters corresponds to series of characters defined by a Hangul word connection definition dictionary; and
a third step of outputting to the information appliance the series of characters with the highest output rank among series of characters corresponding to at least one syllable of the series of characters defined by the Hangul word connection definition dictionary, and storing the rest with lower output ranks in a temporary storage,
wherein the information appliance comprises the Hangul word connection definition dictionary for defining series of characters including at least one syllable and adding a list of words which can be connected to each of the defined series of characters so that each of the words can function grammatically.

27. A method for expressing Hangul, which is used for inputting and outputting Hangul to an information appliance with an input means, the method comprising:
a first step of combining jamos inputted by the input means to generate at least one series of characters including a syllable;
a second step of deciding if the series of characters corresponds to a word defined by a Hangul word dictionary; and
a third step of outputting to the information appliance the series of characters with the highest output rank among series of characters corresponding to at least one syllable of the word defined by the Hangul word dictionary, and storing the rest with lower output ranks in a temporary storage,
wherein the information appliance comprises the Hangul word dictionary for defining words with at least one syllable and grammatical function.

28. A method for expressing Hangul, which is used for inputting and outputting Hangul to an information appliance with an input means which comprises at least one multi key to which a plurality of consonants are assigned, the method comprising:
a first step of combining jamos inputted by the input means to generate at least one series of characters including a syllable;
a second step of deciding if a plurality of the series of characters generated by inputting through the multi key among the generated series of characters correspond to a word defined by a Hangul input assistance dictionary; and
a third step of outputting to the information appliance the series of characters with the highest output rank among the series of characters which correspond to a word defined by the Hangul input assistance dictionary in the second step and storing the rest with lower output ranks in a temporary storage,
wherein the information appliance comprises the Hangul input assistance dictionary for defining a word which has uncertainty in a boundary of series of characters among series of characters which are capable to be generated by inputting through the multi key.

29. The method of claim 28, wherein a syllable is outputted to the information appliance without going through the second step, if the syllable can be generated by inputting through a single key to which a single jamo is assigned and by inputting discontinuously through the multi key.

30. A method for expressing Hangul, which is used for inputting and outputting Hangul to an information appliance with an input means, the method comprising:
a first step of combining jamos inputted by the input means to generate at least one series of characters including a syllable;
a second step of deciding if the Hangul code of the generated series of characters is a completion-type/combination-type;
a third step of converting the Hangul code of the series of characters which has been decided as the completion-type/combination-type to a Hangul jamo code;
a fourth step of deciding if the series of characters correspond converted in the third step corresponds to a series of characters defined by a Hangul word information dictionary;
a fifth step of converting the Hangul jamo code of the series of characters, which has been decided as corresponding to a series of characters defined by the Hangul word information dictionary, to a completion-type/combination-type; and
a sixth step of outputting the series of characters converted in the fifth step to the information appliance,
wherein the information appliance comprises the Hangul word information dictionary for defining series of characters including at least one syllable and adding grammar information to each of the defined series of characters.
